(19) United States
(12) Patent Application Publication
(10) Pub. No.: US 2026/0255800 A1
(43) Pub. Date: Aug. 27, 2026

(54) DISPLAY DEVICE AND ELECTRONIC DEVICE INCLUDING THE SAME

(71) Applicant: Samsung Display Co., Ltd., Yongin-Si (KR)

(72) Inventors: SUNKWANG KIM, Yongin-si (KR); KYEUK LEE, Yongin-si (KR); KANGMOON JO, Yongin-si (KR)

(21) Appl. No.: 19/445,871

(22) Filed: Jan. 12, 2026

(30) Foreign Application Priority Data
Feb. 21, 2025 (KR) 10-2025-0023027

(51) Int. Cl. H10K 59/121; H10K 59/131

(52) U.S. Cl. CPC H10K 59/1213; H10K 59/131

(57) ABSTRACT

A display device includes a first substrate including a display region and a non-display region, a pixel, a first metal layer disposed in the non-display region, and a power line disposed in the non-display region and electrically connected to the pixel. The first metal layer includes a first metal pattern and a second metal pattern, each being electrically connected to the power line through a first contact hole and spaced apart from each other in a first direction. The first metal pattern includes a base portion extending in a second direction, a connection portion disposed closer to the display region than the base portion in the second direction and including the first contact hole, a first protrusion protruding from the base portion toward a first side in the first direction, and a second protrusion protruding from the base portion toward a second side in the first direction.

### CROSS-REFERENCE TO RELATED APPLICATIONS

This application claims priority under 35 U.S.C. § 119 to Korean Patent Application No. 10-2025-0023027, filed on Feb. 21, 2025, the entire contents of which are hereby incorporated by reference.

### BACKGROUND

The present disclosure herein relates to a display device including a filler and an electronic device including the same.

Not only portable electronic devices such as a smartphone and a tablet, which displays an image, but also electronic devices having various sizes, such as a television, a monitor, and a billboard, are being developed. A user prefers an electronic device including a display device with a larger display region and a narrower non-display region.

An electronic device may include various electronic components, such as a display module that displays an image, a processor that controls an operation, and a power module that supplies power. When manufacturing or using an electronic device, static electricity may be introduced into the electronic device and may cause damage to electrically connected electronic components. Accordingly, structures capable of preventing static electricity are continuously being developed.

There is also a demand for the development of a structure which blocks static electricity applied from the outside and also prevents a filler from overflowing into a non-display region during the process of bonding a display device.

### SUMMARY

The present disclosure provides a display device, which may prevent static electricity from being introduced from the outside and also effectively block the flow of a filler, and an electronic device including the same.

According to an embodiment of the inventive concept, a display device includes a first substrate including a display region and a non-display region surrounding at least a portion of the display region, a pixel arranged in the display region of the first substrate, a second substrate facing the first substrate, a filler disposed between the first substrate and the second substrate, a sealing member disposed between the first substrate and the second substrate and overlapping the non-display region, a first metal layer disposed in the non-display region, and a power line disposed in the non-display region and electrically connected to the pixel. The first metal layer includes a first metal pattern and a second metal pattern, each being electrically connected to the power line through a first contact hole, and the second metal pattern is spaced apart from the first metal pattern in a first direction. The first metal pattern includes a base portion extending in a second direction crossing the first direction, a connection portion disposed closer to the display region than the base portion in the second direction and including the first contact hole, a first protrusion protruding from the base portion toward a first side in the first direction, and a second protrusion protruding from the base portion toward a second side in the first direction.

In an embodiment, the sealing member may overlap the base portion, and the filler may overlap the connection portion.

In an embodiment, the second metal pattern may include a base portion extending in the second direction, a connection portion disposed closer to the display region than the base portion in the second direction and including the first contact hole, a first protrusion protruding from the base portion toward the first side in the first direction, and a second protrusion protruding from the base portion toward the second side in the first direction. The second protrusion of the first metal pattern may include a (2-1)-th protrusion and a (2-2)-th protrusion, which are spaced apart from each other in the second direction, and the first protrusion of the second metal pattern may be disposed between the (2-1)-th protrusion and the (2-2)-th protrusion of the first metal pattern in the second direction.

In an embodiment, the display device may further include at least one insulating layer disposed on the first substrate and covering the first metal pattern and the second metal pattern. A step may be defined in the at least one insulating layer between a first region, overlapping the first metal pattern and the second metal pattern, and a second region, disposed between the first metal pattern and the second metal pattern.

In an embodiment, the sealing member may include an upper surface in contact with the second substrate and a lower surface in contact with the at least one insulating layer, and within the second region, a length of the upper surface in the second direction may be greater than a length of the lower surface in the second direction.

In an embodiment, a length of the connection portion in the first direction may be greater than a length of the base portion in the first direction.

In an embodiment, each of the first metal pattern and the second metal pattern may include a plurality of slits extending in the second direction.

In an embodiment, the display device may further include a lower metal layer, and the pixel may include a transistor including a semiconductor pattern and a gate electrode overlapping the semiconductor pattern. The lower metal layer may be disposed between the first substrate and the semiconductor pattern, and the first metal layer and the lower metal layer may include a same material and may be disposed on a same layer.

In an embodiment, the pixel may include a transistor including a semiconductor pattern and a gate electrode overlapping the semiconductor pattern, and the first metal layer and the gate electrode may include a same material and may be disposed on a same layer.

In an embodiment, the display device may further include a second metal layer located in the non-display region and disposed on a different layer from the first metal layer. The second metal layer may include a third metal pattern and a fourth metal pattern spaced apart from the third metal pattern in the first direction, wherein each of the third metal pattern and the fourth metal pattern may be electrically connected to the power line through a second contact hole. The first contact hole may be disposed closer to the display region than the second contact hole in the second direction.

In an embodiment, the third metal pattern may include a base portion extending in the second direction, a connection portion including the second contact hole, a first protrusion protruding from the base portion toward the first side in the first direction, and a second protrusion protruding from the base portion toward the second side in the first direction. The base portion of the third metal pattern may overlap a space between the first metal pattern and the second metal pattern.

In an embodiment, the first protrusion of the third metal pattern may overlap a portion of the base portion of the first metal pattern, and the second protrusion of the third metal pattern may overlap a portion of the base portion of the second metal pattern.

In an embodiment, the display device may further include a lower metal layer, and the pixel may include a transistor including a semiconductor pattern and a gate electrode overlapping the semiconductor pattern. The lower metal layer may be disposed between the first substrate and the semiconductor pattern. The first metal layer and the lower metal layer may include a same material and may be disposed on a same layer, and the second metal layer and the gate electrode may include a same material and may be disposed on a same layer.

In an embodiment, a length of the first protrusion in the second direction may be greater than a length of the second protrusion in the second direction.

In an embodiment, the connection portion may include a first connection portion extending from the base portion in the second direction and partially protruding from the base portion toward the first side in the first direction, and a second connection portion extending from the first connection portion in the second direction and partially protruding from the first connection portion toward the first side in the first direction.

In an embodiment, the display device may further include a second metal layer disposed in the non-display region and disposed on a different layer from the first metal layer, and the first metal layer and the second metal layer may be arranged in a staggered arrangement along the first direction on a plane.

In an embodiment, the display device may further include a second metal layer disposed in the non-display region and disposed on a different layer from the first metal layer, and the second metal layer may include a third metal pattern and a fourth metal pattern spaced apart from the third metal pattern in the first direction, wherein each of the third metal pattern and the fourth metal pattern may be electrically connected to the power line through a second contact hole. The first metal pattern and the second metal pattern may be arranged in a staggered arrangement with the third metal pattern and the fourth metal pattern along the first direction on a plane.

According to an embodiment of the inventive concept, an electronic device includes a display module, a window disposed on the display module, and a power module disposed under the display module. The display module includes a first substrate including a display region and a non-display region surrounding at least a portion of the display region, a pixel arranged in the display region of the first substrate, a second substrate facing the first substrate, a filler disposed between the first substrate and the second substrate, a sealing member disposed between the first substrate and the second substrate and overlapping the non-display region, a first metal layer disposed in the non-display region, and a power line disposed in the non-display region and electrically connected to the pixel. The first metal layer includes a first metal pattern and a second metal pattern, each being electrically connected to the power line through a first contact hole, and the second metal pattern is spaced apart from the first metal pattern in a first direction. The first metal pattern includes a base portion extending in a second direction crossing the first direction, a connection portion disposed closer to the display region than the base portion in the second direction and including the first contact hole, a first protrusion protruding from the base portion toward a first side in the first direction, and a second protrusion protruding from the base portion toward a second side in the first direction.

In an embodiment, the sealing member may overlap the base portion, and the filler may overlap the connection portion.

In an embodiment, the second metal pattern may include a base portion extending in the second direction, a connection portion disposed closer to the display region than the base portion in the second direction and including the first contact hole, a first protrusion protruding from the base portion toward the first side in the first direction, and a second protrusion protruding from the base portion toward the second side in the first direction. The second protrusion of the first metal pattern may include a (2-1)-th protrusion and a (2-2)-th protrusion, which are spaced apart from each other in the second direction, and the first protrusion of the second metal pattern may be disposed between the (2-1)-th protrusion and the (2-2)-th protrusion of the first metal pattern in the second direction.

### BRIEF DESCRIPTION OF THE DRAWINGS

The accompanying drawings are included to provide a further understanding of the inventive concept, and illustrate embodiments of the inventive concept together with the description to explain principles of the inventive concept.

FIG. 1 is a block diagram of an electronic device according to an embodiment of the inventive concept.

FIG. 2 illustrates perspective views of electronic devices according to embodiments of the inventive concept.

FIG. 3 is a perspective view of an electronic device according to an embodiment of the inventive concept.

FIG. 4 is an exploded perspective view of an electronic device according to an embodiment of the inventive concept.

FIG. 5 is a cross-sectional view of a display module according to an embodiment of the inventive concept.

FIG. 6 is a plan view of a display panel according to an embodiment of the inventive concept.

FIG. 7A is an enlarged plan view of a portion of a display panel according to an embodiment of the inventive concept.

FIGS. 7B and 7C are cross-sectional views of a display panel according to an embodiment of the inventive concept.

FIG. 8A is an enlarged plan view of a portion of a display panel according to an embodiment of the inventive concept.

FIG. 8B is a cross-sectional view of a display panel according to an embodiment of the inventive concept.

FIG. 9 is an enlarged plan view of a portion of a display panel according to an embodiment of the inventive concept.

FIG. 10 is an enlarged plan view of a portion of a display panel according to an embodiment of the inventive concept.

### DETAILED DESCRIPTION

In this specification, it will be understood that when an element (or a region, a layer, a portion, or the like) is referred to as being "on", "connected to" or "coupled to" another element, it may be directly disposed on, connected to, or coupled to the other element, or indirectly disposed on, connected to or coupled to the other element with an intervening element disposed therebetween.

Like reference numerals or symbols refer to like elements throughout this specification. In the drawings, the thickness, ratio, and size of the elements are exaggerated for effectively describing the technical feature of the inventive concepts. As used herein, the term "and/or" includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element could be referred to as a second element without departing from the scope of the inventive concept. Similarly, a second element could be referred to as a first element. In this specification, the singular expressions "a", "an" and "the" are intended to include the plural forms as well, unless the context clearly indicates otherwise.

In addition, the terms, such as "below", “under”, "on the lower side", "above", “over”, "on the upper side", or the like, may be used to describe the spatial relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless defined otherwise, all terms (including technical and scientific terms) used herein have the same meaning as commonly understood by one of ordinary skill in the art to which this inventive concept pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the accompanying drawings.

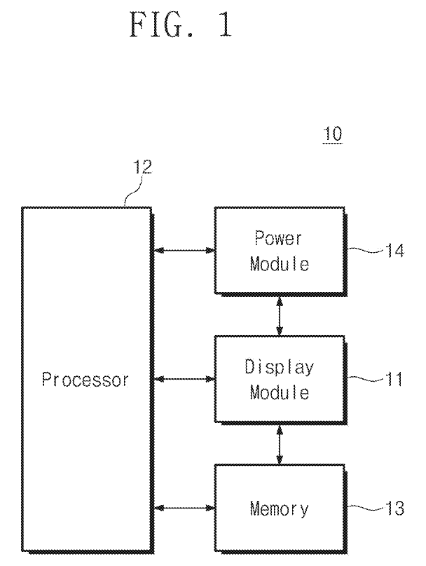

FIG. 1 is a block diagram of an electronic device 10 according to an embodiment of the inventive concept.

Referring to FIG. 1, the electronic device 10 according to an embodiment may include a display module 11, a processor 12, a memory 13, and a power module 14.

The display module 11 may display an image. The image may include a still image as well as a moving image.

The processor 12 may include at least one among a central processing unit (CPU), an application processor (AP), a graphic processing unit (GPU), a communication processor (CP), an image signal processor (ISP), and a controller. The processor 12 may be configured to control an operation of the display module 11.

The memory 13 may store data information required for an operation of the processor 12 or the display module 11. When the processor 12 executes an application stored in the memory 13, an image data signal and/or an input control signal may be transferred to the display module 11, and the display module 11 may process the received signal and output image information through a display screen.

The power module 14 may include a power supply module, such as a power adaptor or a battery device, and a power conversion module that converts power supplied from the power supply module to generate power required for an operation of the electronic device 10.

At least one of individual components of the electronic device 10 may be included in display devices according to embodiments. Additionally, among individual modules that are functionally included in a single module, some may be included in the display device, and others may be provided separately from the display device. For example, the display device may include the display module 11, and the processor 12, the memory 13, and the power module 14 may be provided in the form of a separate component in the electronic device 10 other than the display device.

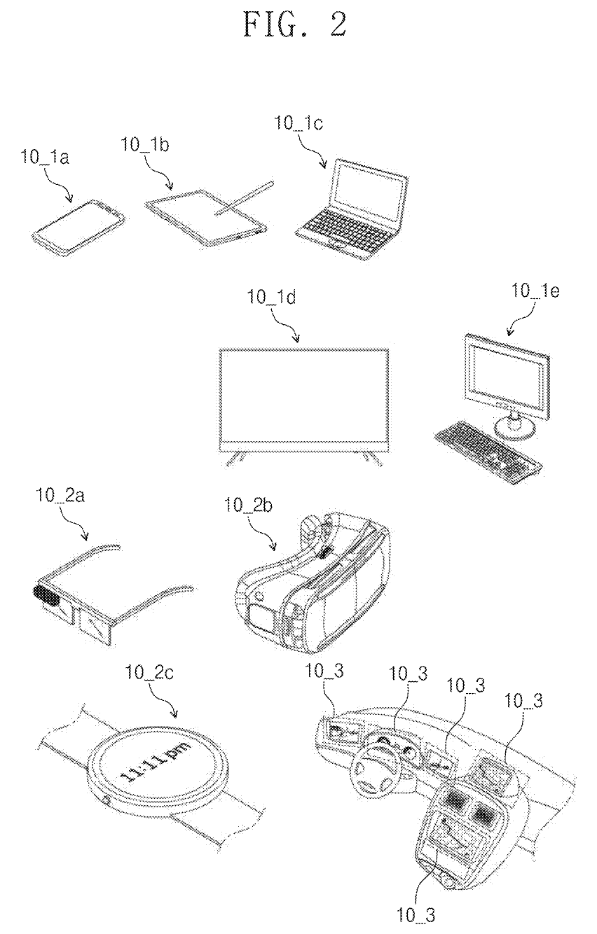

FIG. 2 illustrates perspective views of electronic devices according to various embodiments.

Referring to FIG. 2, various electronic devices, to which display devices according to embodiments are applied, may include not only an image displaying electronic device, such as a smart phone 10_1a, a tablet PC 10_1b, a laptop 10_1c, a TV 10_1d, or a desk monitor 10_1e, but also a wearable electronic device including a display module, such as smart glasses 10_2a, a head-mounted display 10_2b, or a smart watch 10_2c, and a vehicular electronic device 10_3 including a display module, such as a car dashboard, a center fascia, a center information display (CID) disposed in a dashboard, or a room mirror display.

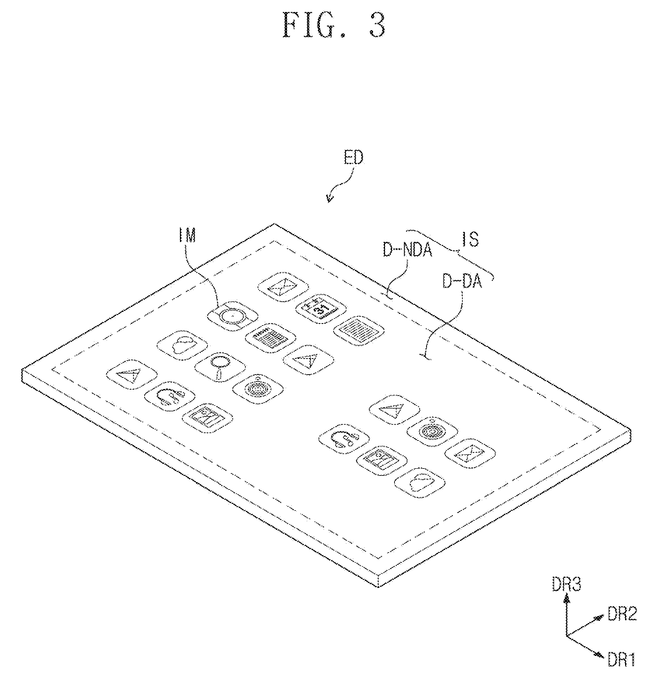

Hereinafter, an electronic device ED, as an example among the various electronic devices above, will be described in detail with reference to FIGS. 3 to 6. FIG. 3 is a perspective view of the electronic device ED according to an embodiment of the inventive concept.

Referring to FIG. 3, the electronic device ED may have a rectangular shape having long sides extending in a first direction DR1 and short sides extending in a second direction DR2. However, an embodiment of the inventive concept is not limited thereto, and the electronic device ED may have various shapes, such as a circular shape and a polygonal shape.

The electronic device ED may display an image IM in a third direction DR3 through a display surface IS parallel to a plane defined by the first direction DR1 and the second direction DR2. The third direction DR3 may be substantially parallel to a normal direction of the display surface IS. The display surface IS on which the image IM is displayed may correspond to a front surface of the electronic device ED. The image IM may include a still image as well as a moving image. In FIG. 3, icon images are illustrated as an example of the image IM.

In the embodiment, a front surface (or upper surface) and a rear surface (or lower surface) of each member constituting the electronic device ED may be defined based on the third direction DR3. The front surface and the rear surface may be opposed to each other in the third direction DR3, and a normal direction of each of the front surface and the rear surface may be parallel to the third direction DR3. A separate distance between the front surface and the rear surface, which are defined along the third direction, may correspond to a thickness of the member.

In the specification, “on a plane” or “in a plan view” may be defined as a state viewed from the third direction DR3. In this specification, “on a cross-section” may be defined as a state viewed from the first direction DR1 or the second direction DR2. However, the directions indicated by the first to third directions DR1, DR2, and DR3 are relative concepts and may thus be changed into other directions.

FIG. 3 illustrates the electronic device ED having a flat display surface IS as an example. However, the shape of the display surface IS of the electronic device ED is not limited thereto and may be a curved shape or a three-dimensional shape.

The electronic device ED may be flexible. The “flexible” means a property capable of being bent and may include any structure from a fully foldable structure to a structure that may be bent to a level of several nanometers. For example, the flexible electronic device ED may include a curved device or a foldable device. However, an embodiment of the inventive concept is not limited thereto, and the electronic device ED may be rigid.

The display surface IS of the electronic device ED may include a display portion D-DA and a non-display portion D-NDA. The display portion D-DA may be a portion on which or through which the image IM is displayed, and a user may view the image IM through the display portion D-DA. Although the display portion D-DA having a quadrilateral shape on a plane is illustrated as an example, the display portion D-DA may have various shapes according to the designs of the electronic device ED.

The non-display portion D-NDA may be a portion on which or through which the image IM is not displayed. The non-display portion D-NDA may have a color and may block light. The non-display portion D-NDA may be adjacent to the display portion D-DA. For example, the non-display portion D-NDA may be disposed on the outer side of the display portion D-DA and surround at least one side of the display portion D-DA. For example, the non-display portion D-NDA may be adjacent only to one side of the display portion D-DA or may be disposed on the side of the electronic device ED rather than being disposed on the front surface of the electronic device ED.

The electronic device ED according to an embodiment may detect an external input applied from the outside. The external input may have various types of inputs, which are provided from the outside, such as pressure, temperature, and light. The external input may include not only an input in contact with the electronic device ED (for example, touch by a user’s hand or by a pen) ED but also an input in proximity to the electronic device ED (for example, hovering).

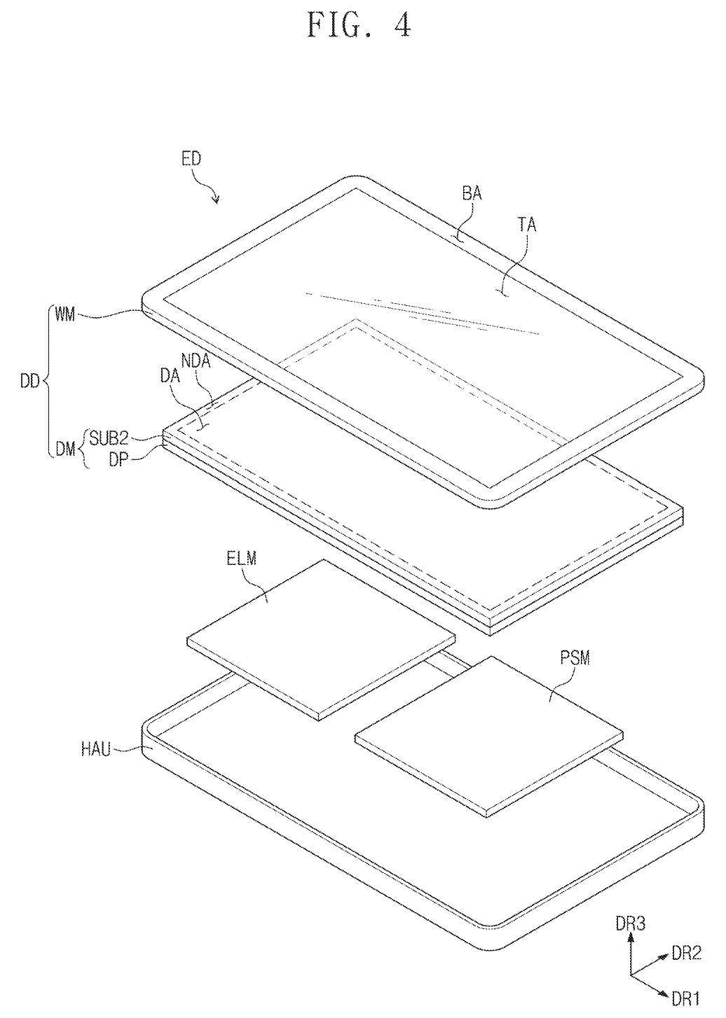

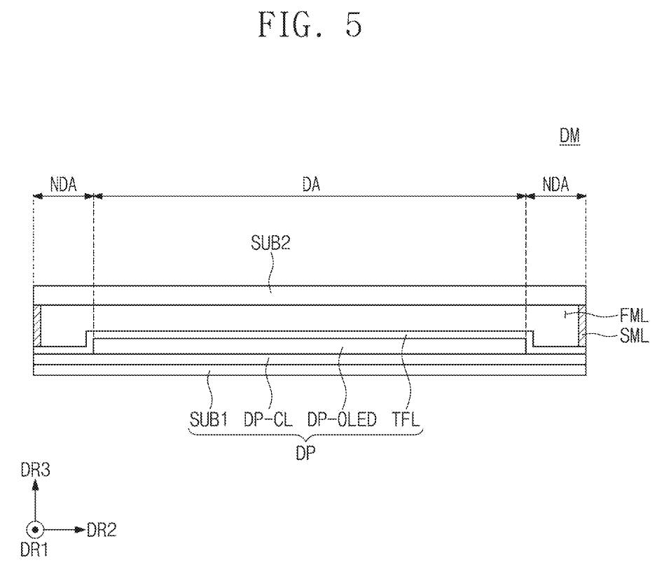

FIG. 4 is an exploded perspective view of an electronic device ED according to an embodiment of the inventive concept. FIG. 5 is a cross-sectional view of a display module DM according to an embodiment of the inventive concept.

Referring to FIGS. 4 and 5, the electronic device ED may include a display device DD, an electronic module ELM, a power module PSM, and a housing HAU. The display device DD may include a window WM and the display module DM. The display module DM may include a display panel DP and an upper member SUB2 disposed on the display panel DP.

The window WM and the housing HAU may be coupled to form the exterior of the electronic device ED and provide an internal space capable of accommodating components of the electronic device ED such as the display module DM.

The window WM may be disposed on the display module DM. The window WM may protect the display module DM from an external impact. A front surface of the window WM may correspond to the display surface IS of the electronic device ED described above. The front surface of the window WM may include a transmission region TA and a bezel region BA.

The transmission region TA of the window WM may be an optically transparent region. The window WM may transmit an image provided from the display module DM through the transmission region TA, and a user may view the image. The transmission region TA may correspond to the display portion D-DA of the electronic device ED described above.

The window WM may include an insulating material that is optically transparent. For example, the window WM may include glass, sapphire, or plastic. The window WM may have a single-layer or multi-layer structure. The window WM may further include functional layers, such as an anti-fingerprint layer, a phase control layer, and/or a hard coating layer, which are disposed on the optically transparent substrate.

A bezel region BA of the window WM may be provided as a region in which a material having a predetermined color is deposited, coated, or printed on a transparent substrate. The bezel region BA of the window WM may prevent a component of the display module DM, which is disposed under the bezel region BA, from being visible from the outside. The bezel region BA may correspond to the non-display portion D-NDA of the electronic device ED described above.

The display module DM may be disposed under the window WM. The display module DM may display an image in response to an electrical signal. The display module DM may include a display region DA and a non-display region NDA adjacent to the display region DA.

The display region DA may display an image in response to an electrical signal. The display region DA of the display module DM may overlap the transmission region TA of the window WM. In the specification, the wording, “one region/portion overlaps another region/portion,” is not limited to a case where the two regions/portions overlapping with each other have the same area and/or same shape. An image that is output from the display region DA may be perceived through the transmission region TA from the outside.

The non-display region NDA may be disposed around the display region DA. For example, the non-display region NDA may surround at least one side of the display region DA. However, an embodiment of the inventive concept is not limited thereto, and the non-display region NDA may be defined as various shapes. The non-display region NDA may be a region in which a driving circuit or driving line for driving elements disposed in the display region DA, various signal lines for providing an electrical signal, and pads are disposed. The non-display region NDA of the display module DM may overlap the bezel region BA of the window WM, and the bezel region BA may prevent components disposed in the non-display region NDA from being visible from the outside.

The display panel DP according to an embodiment may be a light-emitting display panel. However, the present disclosure is not particularly limited thereto. For example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, and the like. Hereinafter, for convenience of the description, the display panel DP is described as an organic light-emitting display panel.

The display panel DP may include a first substrate SUB1, a circuit layer DP-CL, a display element layer DP-OLED, and an encapsulation layer TFL.

The first substrate SUB1 may provide a base surface on which the circuit layer DP-CL is disposed. The first substrate SUB1 may be a rigid substrate or a flexible substrate.

The circuit layer DP-CL may be disposed on the first substrate SUB1. The circuit layer DP-CL may include driving elements such as a transistor, signal lines and signal pads. The display element layer DP-OLED may include light-emitting elements that are disposed overlapping the display region DA. The light-emitting elements of the display element layer DP-OLED may be electrically connected to the driving elements of the circuit layer DP-CL and may output light through the display region DA in response to signals of the driving elements.

The encapsulation layer TFL may be disposed on the display element layer DP-OLED to seal the light-emitting elements. The encapsulation layer TFL may include a plurality of thin films. The thin films of the encapsulation layer TFL may be disposed to enhance optical efficiency of the light-emitting elements or protect the light-emitting elements from foreign substances, such as dust, particles, oxygen, moistures, and the like, from outside.

A second substrate SUB2 may be disposed on the display panel DP. The second substrate SUB2 may be arranged to face the first substrate SUB1 of the display panel DP. After being positioned on the display panel DP, the second substrate SUB2 may be coupled to the display panel DP through a sealing member SML during a bonding process of the display module DM.

Although not illustrated, the lower surface of the second substrate SUB2 may further include an optical member that converts a wavelength of light provided from the display panel DP, that is, source light, or selectively transmits the source light. For example, the optical member may include light control patterns capable of converting an optical property of the source light provided from the display panel DP. The light control patterns may control the color purity or color reproduction of the light emitted from the electronic device ED and prevent reflection of the external light incident from the outside of the electronic device ED.

Additionally, the optical member may include quantum dots that convert the wavelength of the source light provided from the display panel DP or include a light control layer that transmits the source light. The source light that passes through the light control layer may have color that is different from that of the source light.

The optical member may further include color filters, and the color filters may transmit or absorb light that passes through the light control layer depending on colors. A color filter layer may absorb light, which is not converted by the light control layer, to prevent degradation of the color purity of the electronic device ED. Additionally, the color filter layer may filter external light into the same color as pixels to prevent reflection of the external light.

The sealing member SML is disposed between the first substrate SUB1 and the second substrate SUB2 and overlaps the non-display region NDA of the display module DM. The sealing member SML may couple the first substrate SUB1 to the second substrate SUB2. The sealing member SML may be disposed along the outer edges of the non-display region NDA and prevent foreign substances, such as oxygen, moisture, and the like, from entering the interior of the display module DM from the outside of the display module DM. The sealing member SML may be formed from a sealant including a curable resin. For example, the sealing member SML may include frit or an organic adhesive such as an epoxy-based resin and an acrylate-based resin.

A filler FML may be disposed between the first substrate SUB1 and the second substrate SUB2 to fill the space between the first substrate SUB1 and the second substrate SUB2. The filler FML may fill the space between the second substrate SUB2 and the display panel DP. The filler FML may function as a buffer between the display panel DP and the second substrate SUB2. In an embodiment, the filler FML may absorb impact, thereby increasing the strength of the display module DM.

The filler FML may overlap at least a portion of the display region DA and be formed from a filling resin including a polymer resin. For example, the filler FML may include an acrylate-based resin, an epoxy-based resin, silicone-based resin, polyimide or the like.

Referring again to FIG. 4, the electronic module ELM and the power module PSM are disposed under the display module DM. The electronic module ELM and the power module PSM may be electrically connected through a separate circuit board.

The power module PSM may provide power required for an operation of the electronic device ED. For example, the power module PSM may include a typical battery module.

The electronic module ELM may include various functional modules that operate the electronic device ED. For example, the electronic module ELM may include a control module, a wireless communication module, an image input module, an audio input module, an audio output module, a memory, an optical module, an external interface module, and the like. The electronic module ELM may include a main circuit board, and the above-described modules of the electronic module ELM may be mounted on the main circuit board or electrically connected to the main circuit board through a separate circuit board.

The control module among the electronic modules ELM may control overall operations of the electronic device ED. For example, the control module may activate or deactivate the display module DM in accordance with an input of a user. The control module may include at least one microprocessor. The optical module among the electronic modules ELM may include a camera module, a proximity sensor, a biometric sensor that recognizes a portion of the user’s body (for example, a fingerprint, iris, or face), or a lamp that outputs light.

The housing HAU may be disposed under the display module DM to accommodate the display module DM, the electronic module ELM, and the power module PSM. The housing HAU may absorb the external impact applied to the display module DM and protect the display module by preventing a foreign substance/moisture from penetrating into the display module DM. For example, the housing HAU may be provided in the form in which multiple accommodating members are coupled together.

The electronic device ED may further include an input sensing module. The input sensing module may acquire coordinate information about an external input applied from the outside of the electronic device ED. The input sensing module may be driven through various methods, such as a capacitive, resistive, infrared, or pressure method, and an embodiment of the inventive concept is not limited thereto.

In an embodiment, the input sensing module may be disposed on the display module DM. The input sensing module may be directly disposed on the display module DM through continuous processes. However, the present disclosure is not limited thereto. For example, the input sensing module may be manufactured separately from the display module DM and then coupled to the display module DM by an adhesive layer. However, an embodiment of the inventive concept is not limited thereto, and the input sensing module may be disposed between components of the display module DM. For example, the input sensing module may be disposed between the display panel DP and a light control member.

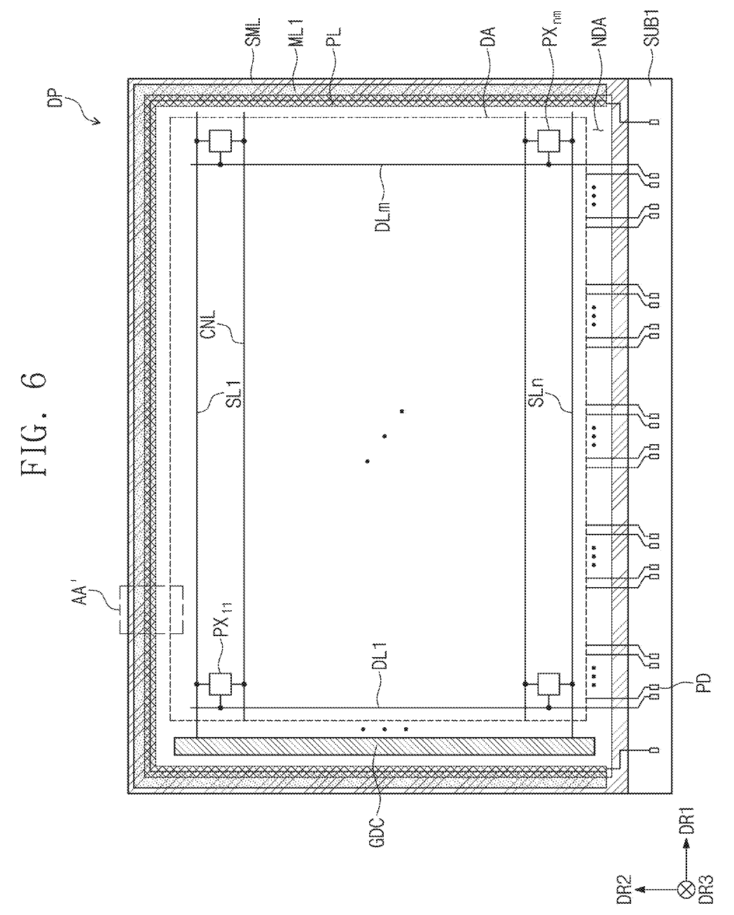

FIG. 6 is a plan view of a display panel DP according to an embodiment of the inventive concept.

Referring to FIG. 6, the display panel DP may include pixels PX₁₁ to PXₙₘ disposed in the display region DA, signal lines SL1 to SLn and DL1 to DLm electrically connected to the pixels PX₁₁ to PXₙₘ, and a power line PL. Here, “m” and “n” are natural numbers. The display panel DP may include a driving circuit GDC and pads PD disposed in the non-display region NDA.

Each of the pixels PX₁₁ to PXₙₘ may include a light-emitting element and a pixel driving circuit including a plurality of transistors (for example, a switching transistor, a driving transistor, and the like) connected to the light-emitting element, and at least one capacitor. The pixels PX₁₁ to PXₙₘ may emit light in response to electrical signals applied to the pixels PX₁₁ to PXₙₘ through scan lines SL1 to SLn and data lines DL1 to DLm. FIG. 6 illustrates the pixels PX₁₁ to PXₙₘ arranged in a matrix form as an example, but the arrangement of the pixels PX₁₁ to PXₙₘ is not limited thereto.

The signal lines SL1 to SLn and DL1 to DLm may include scan lines SL1 to SLn and data lines DL1 to DLm. Each of the pixels PX₁₁ to PXₙₘ may be connected to a corresponding scan line among the scan lines SL1 to SLn and a corresponding data line among the data lines DL1 to DLm. Each of the pixels PX₁₁ to PXₙₘ may receive data voltages applied from the corresponding data line among the data lines DL1 to DLm. Additional signal lines may be provided on the display panel DP depending on the design of the pixel driving circuit of the pixels PX₁₁ to PXₙₘ.

The driving circuit GDC may include a gate driving circuit. The gate driving circuit may generate gate signals and sequentially output the gate signals to the scan lines SL1 to SLn. The gate driving circuit may further output another control signal to the pixel driving circuit of the pixels PX₁₁ to PXₙₘ.

The driving circuit GDC and the pixels PX₁₁ to PXₙₘ according to an embodiment may include a plurality of transistors formed through a low temperature polycrystalline silicon (LTPS) process, a low temperature polycrystalline oxide (LTPO) process, or an oxide semiconductor process.

The pads PD may be arranged spaced apart from each other in a first direction DR1 and disposed on the non-display region NDA. The pads PD may be portions to which the circuit board (not illustrated) that provides a control signal controlling an operation of the driving circuit GDC of the display panel DP is electrically connected.

Each of the pads PD may be connected to a corresponding signal line among the signal lines SL1 to SLn and DL1 to DLm and connected to a corresponding pixel PX₁₁ to PXₙₘ through the signal line. The pads PD may have an integral shape with the signal lines SL1 to SLn and DL1 to DLm. However, an embodiment of the inventive concept is not limited thereto, and the pads PD may be disposed on a layer different from a layer on which the signal lines SL1 to SLn and DL1 to DLm are disposed, and may thus be connected to the signal lines SL1 to SLn and DL1 to DLm through contact holes.

FIG. 6 illustrates the power line PL disposed in the non-display region NDA surrounding the display region DA as an example, but the power lines PL may be provided in plurality, and a power line disposed at one side of the display region DA may be further included.

The power line PL illustrated in FIG. 6 may receive a first voltage ELVDD or a second voltage ELVSS having a lower level than the first voltage ELVDD. For example, the power line PL may be connected to a portion of the pads PD and receive the first voltage ELVDD applied from an external power source. The corresponding pixels PX₁₁ to PXₙₘ may be connected through the power line PL, and the first voltage ELVDD may be provided to the corresponding pixels PX₁₁ to PXₙₘ through the power line PL. Accordingly, a driving current may flow into the light-emitting element of the pixels PX₁₁to PXₙₘ to emit light.

In an embodiment, the power line PL disposed in the non-display region NDA may partially surround the display region DA. For example, the power line PL may surround the border of the display region DA in a loop shape with a lower portion of the first substrate SUB1, on which the pads PD are disposed, being opened. The power line PL may be disposed on the outer side of the driving circuit GDC.

Connection lines CNL may extend in the first direction DR1 and be arranged in the second direction DR2. The connection lines CNL may be connected to the power line PL and corresponding pixels PX₁₁ to PXₙₘ. The first voltage ELVDD may be applied to corresponding pixels PX₁₁ to PXₙₘ through the power lines PL and the connection lines CNL that are connected to each other.

In an embodiment, the power line PL may be connected to a portion of the pads PD and receive the second voltage ELVSS applied from the power source. The power line PL may provide the second voltage ELVSS to a counter electrode of the corresponding pixel PX₁₁ to PXₙₘ.

As described above, the sealing member SML may be disposed in the non-display region NDA and entirely surround the display region DA on a plane. The sealing member SML may partially overlap the power line PL.

According to an embodiment of the inventive concept, the display panel DP may include a first metal layer ML1 disposed in the non-display region NDA. The first metal layer ML1 may be disposed on the first substrate SUB1 and partially overlap the sealing member SML. On a plane, the first metal layer ML1 may be arranged along edges of the first substrate SUB1 and partially overlap the display region DA. However, an embodiment of the inventive concept is not limited thereto, and the first metal layer ML1 may be arranged along all of the edges of the first substrate SUB1 and entirely overlap the display region DA.

The first metal layer ML1 may be disposed in the outermost side of the first substrate SUB1 and prevent a static electricity from flowing into the interior of the electronic device ED (see FIG. 4) from the outside during use of the electronic device ED (see FIG. 4). Additionally, the first metal layer ML1 may discharge or disperse static electricity generated during the manufacture or use of the display panel DP. Accordingly, the first metal layer ML1 may prevent the static electricity from entering the display region DA and avoid damage to the pixels PX₁₁ to PXₙₘ caused by the flow of the static electricity into the display region DA, thereby preventing defects of the display panel DP.

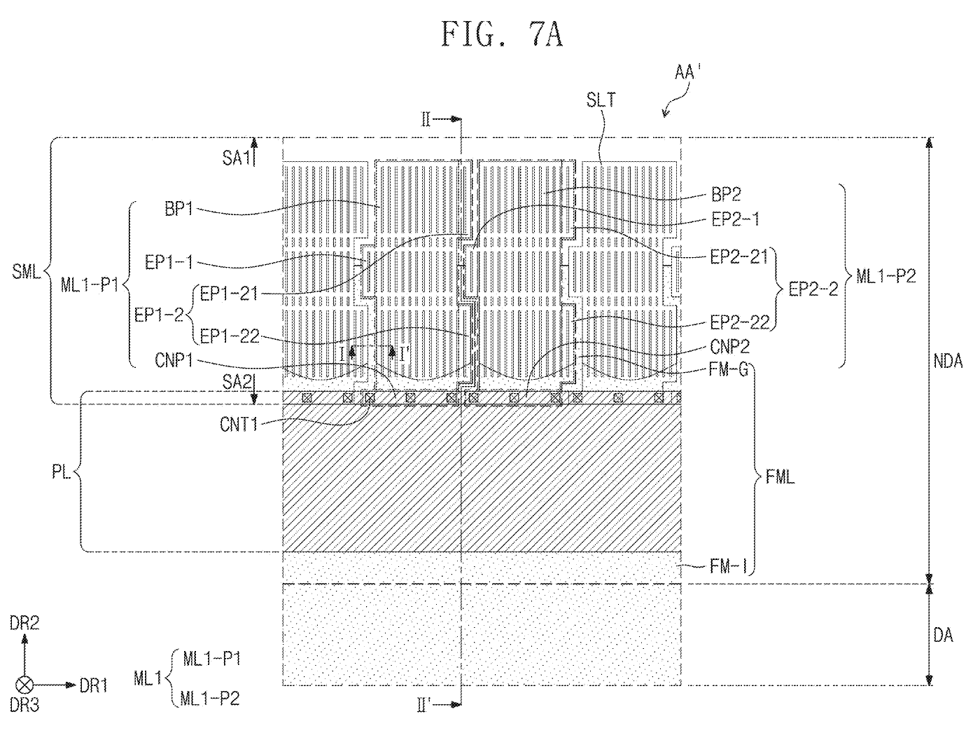

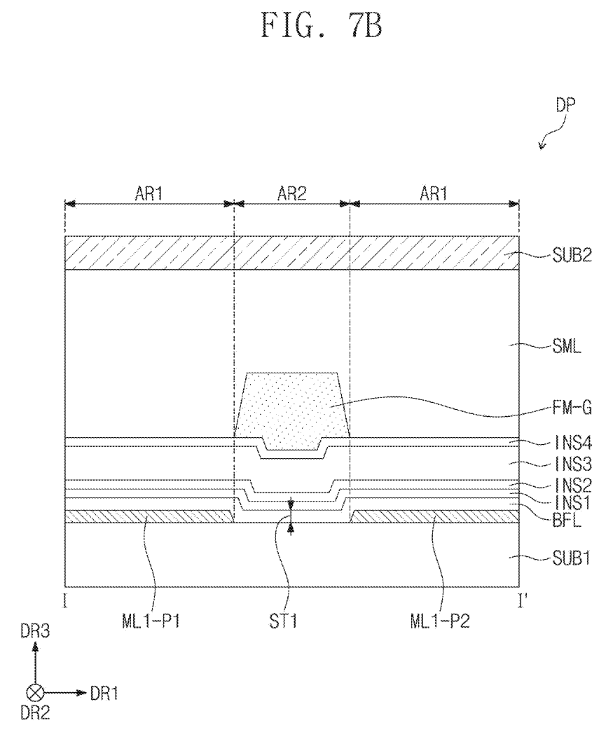

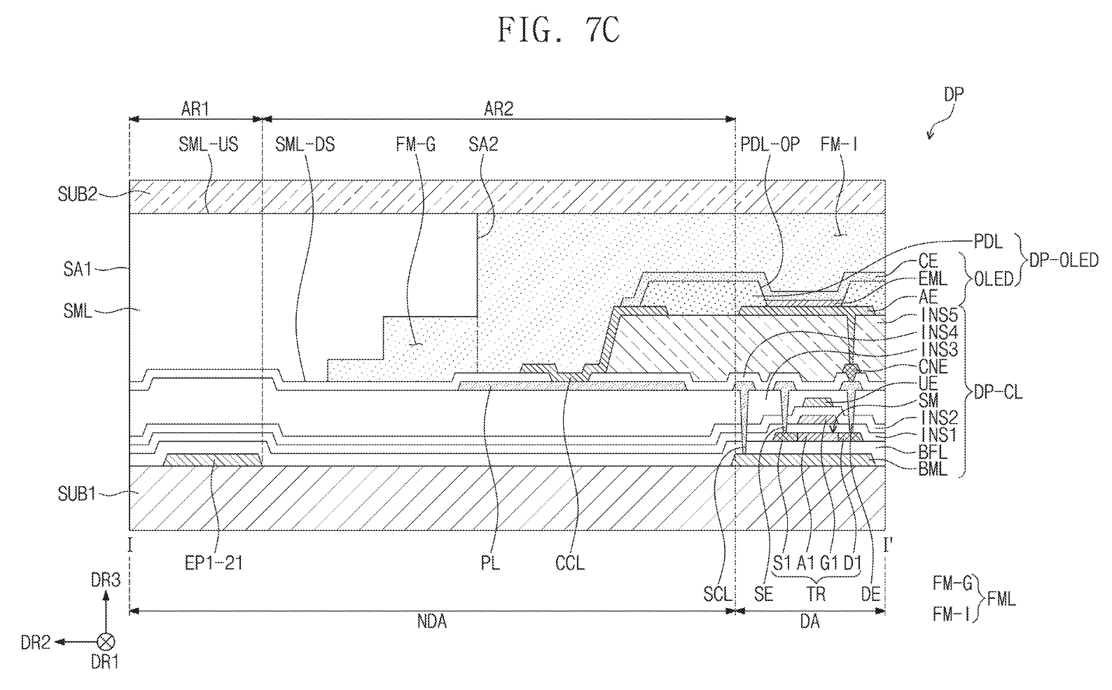

FIG. 7A is an enlarged plan view of a portion of a display panel according to an embodiment of the inventive concept. That is, FIG. 7A is an enlarged plan view schematically illustrating a region AA' in FIG. 6.

Referring to FIG. 7A, the first metal layer ML1 may be disposed on the non-display region NDA. The first metal layer ML1 may include a first metal pattern ML1-P1 and a second metal pattern ML1-P2 that are disposed spaced apart from each other on a plane. The first metal pattern ML1-P1 and the second metal pattern ML1-P2 are illustrated as an example, and the number of metal patterns is not limited. The first metal pattern ML1-P1 and the second metal pattern ML1-P2 may be spaced apart in the first direction DR1 or in the second direction DR2 (that is, spaced apart from each other along the edge direction of the first substrate SUB1 (see FIG. 6)). In other words, each of the first metal layers ML1 may be disposed in an island shape or an isolated shape.

In an embodiment, each of the first metal pattern ML1-P1 and the second metal pattern ML1-P2 may include a plurality of slits SLT. Each of the slits SLT may be formed to penetrate through a corresponding metal pattern in the third direction DR3 that is a thickness direction of the metal pattern. The slits SLT may be spaced apart from each other in the first direction DR1 and the second direction DR2, and may have a shape extending in the second direction DR2. However, the present disclosure is not limited thereto. For example, the slits SLT of the first metal pattern ML1-P1 and the second metal pattern ML1-P2, which are included in the first metal layer ML1 disposed in the right side or the left side of the first substrate SUB1 (see FIG. 6), may extend in the first direction DR1. Hereinafter, for convenience of the description, only the structure of the first metal pattern ML1-P1 and the second metal pattern ML1-P2 disposed in the AA’ (see FIG. 6) is mainly discussed. However, it should be understood that the first metal layer ML1 in the right side or the left side of the first substrate SUB1 would include the first metal pattern ML1-P1 and the second metal pattern ML1-P2, spaced apart from each other in the second direction DR2, and the first metal layer ML1 in the right side or the left side of the first substrate SUB1 would include the same or the substantially similar structure as the first metal layer ML1 in the AA’ discussed below.

The first metal pattern ML1-P1 and the second metal pattern ML1-P2 may be spaced apart from each other, and each of the metal patterns may include a plurality of slits SLT such that the total area of the first metal layer ML1 on a plane is reduced. During a process of manufacturing the electronic device ED (see FIG. 4), as the area of the first metal layer ML1 decreases, it is possible to prevent concentration and accumulation of charges of the static electricity charges caused by physical friction or the like. Accordingly, the charges of the first metal layer ML1 may be reduced from flowing into the display region DA, and defects caused by the static electricity such as cracks in the insulating layers or circuit short may be prevented.

The first metal layer ML1 may overlap the sealing member SML and be disposed in the outer edge of the non-display region NDA. Therefore, the static electricity applied from the outside may be preemptively induced by the first metal layer ML1, and may be prevented from flowing into the display region DA through other paths.

The first metal layer ML1 may be electrically connected to the power line PL through a first contact hole CNT1. The first metal layer ML1 may overlap at least a portion of the power line PL disposed in the non-display region NDA. The first contact hole CNT1 may be formed in an area where connection portions CNP1 and CNP2 to be described later are formed, and may extend to a portion of the power line PL. In other words, the first contact hole CNT1 may be formed in an area where each of the connection portion CNP1 of the first metal pattern ML1-P1 and the connection portion CNP2 of the second metal pattern ML1-P2, in which the plurality of slits SLT are not disposed, is formed, and may extend to a portion of the power line PL.

The first metal layer ML1 may receive the second voltage ELVSS from the power line PL. That is, the first metal layer ML1 may receive a constant voltage corresponding to the common power supply voltage to stably discharge or disperse static electricity.

The sealing member SML may include a first side surface SA1 facing the non-display region NDA and a second side surface SA2 facing the display region DA. The sealing member SML may prevent external moisture and foreign substances from penetrating into the display region DA and enhance structural robustness to improve impact resistance and durability. The sealing member SML may partially overlap the power line PL at the second side surface SA2 thereof, but an embodiment of the inventive concept is not limited thereto.

On a plane, The filler FML may include a first filling portion FM-I and a second filling portion FM-G, defined with respect to the sealing member SML. The first filling portion FM-I may overlap the display region DA and may be disposed inside the second side surface SA2 of the sealing member SML. The first filling portion FM-I may partially overlap the power line PL. During a bonding process of the display panel DP (see FIG. 6), the second filling portion FM-G may flow out in the second direction DR2 and may overlap the sealing member SML as well as a partial region of the first metal layer ML1. The second filling portion FM-G may define the boundary of the filler FML in the non-display region NDA.

The filler FML is applied onto the first substrate SUB1 (see FIG. 5) during a process of bonding the first substrate SUB1 (see FIG. 5) and the second substrate SUB2 (see FIG. 5), and the filler FML flows in the second direction DR2 during a process of curing the sealants. Accordingly, a portion of the filler FML may flow into a space between the metal pattens ML1-P1 and ML1-P2, and the second filling portion FM-G, which overlaps at least a portion of the sealing member SML, may be defined.

On a plane, the first metal pattern ML1-P1 includes a base portion BP1 that extends in the second direction DR2 crossing the first direction DR1, the connection portion CNP1 that is closer to the display region DA in the second direction DR2 than the base portion BP1 and includes the first contact hole CNT1, at least one first protrusion EP1-1 that protrudes from the base portion BP1 toward one side in the first direction DR1, and at least one second protrusion EP1-2 that protrudes from the base portion BP1 toward the other side in the first direction DR1.

In an embodiment, on a plane, the second metal pattern ML1-P2 may include a base portion BP2 that extends in the second direction DR2, a connection portion CNP2 that is closer to the display region DA in the second direction DR2 than the base portion BP2 and includes the first contact hole CNT1, at least one first protrusion EP2-1 that protrudes from the base portion BP2 toward one side in the first direction DR1, and at least one second protrusion EP2-2 that protrudes from the base portion BP2 toward the other side in the first direction DR1.

Hereinafter, the base portion BP1, the connection portion CNP1, the first protrusion EP1-1, and the second protrusion EP1-2 of the first metal pattern ML1-P1 are described but such description may also be applied to the second metal pattern ML1-P2 and to all separated metal patterns of the first metal layer ML1.

In an embodiment, the base portion BP1 may overlap the sealing member SML. In FIG. 7A, the base portion BP1 may have a rectangular shape extending in the second direction DR2. For example, the length of the base portion BP1 in the first direction DR1 may be about 0.05 mm to about 1 mm, and the length of the base portion BP1 in the second direction DR2 may be greater than the length of the base portion BP1 in the first direction DR1.

The base portion BP1 may include a plurality of slits SLT spaced apart from each other in the first direction DR1. The slits SLT may extend in the second direction DR2 and be arranged in a matrix of rows and columns. As illustrated in FIG. 7A, the slits SLT of the base portion BP1 may be arranged in a 11X5 matrix form, for example, having 11 slits in the first direction DR1 and 5 slits in the second direction DR2. Additionally, the slits SLT may have different lengths in the second direction DR2.

In an embodiment, the connection portion CNP1 may overlap the filler FML and also overlap the sealing member SML. In the connection portion CNP1, the first metal layer ML1 may be electrically connected to the power line PL through the first contact hole CNT1. Although FIG. 7A illustrates three first contact holes CNT1 spaced apart from each other in the first direction DR1 in the connection portion CNP as an example, the number of the first contact holes CNT1 in the connection portion CNP is not limited thereto.

In an embodiment, the length of the connection portion CNP1 in the first direction DR1 may be greater than the length of the base portion BP1 in the first direction DR1. Although FIG. 7A illustrates, as an example, the connection portion CNP1 extending toward one side in the first direction DR1 that is the same as the direction in which the first protrusion EP1-1 protrudes, the connection portion CNP1 may also extend toward the other side in the first direction DR1 in which the second protrusion EP1-2 protrudes. As the length of the connection portion CNP1 in the first direction DR1 is greater than the length of the base portion BP1 in the first direction DR1, the path, through which the second filling portion FM-G flows into spaces between the metal patterns during a process of bonding the display panel DP (see FIG. 6), may be extended. That is, on a plane, as a bending portion is added at an entrance through which the second filling portion FM-G flows, the flow of the filler FML may be suppressed or blocked and the second filling portion FM-G may be prevented from overflowing into the outside of the first metal layer ML1. Accordingly, it is possible to suppress the sealing member SML from being displaced in the second direction DR2 by the second filling portion FM-G, thereby ensuring a sufficient sealing area and enhancing the durability and the structural stability of the display device.

Referring to FIG. 7A, the first protrusion EP1-1 and the second protrusion EP1-2 may protrude from the base portion BP1 toward one side and the other side in the first direction DR1, respectively. That is, the first protrusion EP1-1 and the second protrusion EP1-2 may respectively protrude toward opposite sides in the first direction DR1. Each of the first protrusion EP1-1 and the second protrusion EP1-2 is exemplarily illustrated as having a rectangular shape extending in the second direction DR2.

The first protrusion EP1-1 is illustrated as a single protrusion, and the second protrusion EP1-2 is illustrated as two protrusions including a (2-1)-th protrusion EP1-21 and a (2-2)-th protrusion EP1-22, but the number of the protrusions is not limited. For example, each of the first protrusion EP1-1 and the second protrusion EP1-2 may further include a plurality of sub-protrusions spaced apart in the second direction DR2, and therefore, the path, through which the filler FML flows in a space between metal patterns ML1-P1 and ML1-P2, may be extended. As the flow of the second filling portion FM-G is blocked in a space region between the metal patterns ML1-P1 and ML1-P2, the area of the second filling portion FM-G may be reduced. Accordingly, it is possible to suppress the sealing member SML from being pushed in the second direction DR2 by the second filling portion FM-G. That is, during a cutting process in which cells of the display panel are cut and separated into individual units, a cell cutting defect, which would occur due to the sealing member SML being displaced in the second direction DR2, may be reduced.

In an embodiment, the first protrusion EP2-1 of the second metal pattern ML1-P2 may be disposed between the (2-1)-th protrusion EP1-21 and the (2-2)-th protrusion EP1-22 of the first metal pattern ML1-P1. That is, the (2-1)-th protrusion EP1-21 and the (2-2)-th protrusion EP1-22 of the first metal pattern ML1-P1 may be space apart from each other in the second direction DR2, and the first protrusion EP2-1 of the second metal pattern ML1-P2 may be disposed between the (2-1)-th protrusion EP1-21 and the (2-2)-th protrusion EP1-22 of the first metal pattern ML1-P1 in the second direction DR2.

Each of FIGS. 7B and 7C is a cross-sectional view of a display panel DP according to an embodiment of the inventive concept. FIG. 7B is a cross-sectional view of the display panel DP taken along a line I-I' of FIG. 7A., and FIG. 7C is a cross-sectional view of the display panel DP taken along a line II-II' of FIG. 7A.

FIG. 7B illustrates cross-sections of the first metal pattern ML1-P1 and the second metal pattern ML1-P2 in the first direction DR1. At least one insulating layer, which covers the first metal pattern ML1-P1 and the second metal pattern ML1-P2, may be disposed on the first substrate SUB1. For example, the buffer layer BFL may cover the first metal pattern ML1-P1 and the second metal pattern ML1-P2. First insulating layer INS1 to fourth insulating layer INS4 may be disposed on the buffer layer BFL. The buffer layer BFL, the first insulating layer INS1, the second insulating layer INS2, the third insulating layer INS3, and the fourth insulating layer INS4 may be referred to as a plurality of insulating layers. A region of the plurality of insulating layers, which overlaps the first metal pattern ML1-P1 and the second metal pattern ML1-P2, may be referred to as a first region AR1, and a region of the plurality of insulating layers, which is disposed between the first metal pattern ML1-P1 and the second metal pattern ML1-P2, may be referred to as a second region AR2.

In an embodiment, since the first metal pattern ML1-P1 and the second metal pattern ML1-P2 are spaced apart from each other in the first direction DR1, a step ST1 may be formed in the second region AR2. As the filler flows into the second region AR2 in which the step ST1 is defined, the second filling portion FM-G that pushes the sealing member SML in the second direction DR2 may be defined in the second region AR2.

Referring to FIGS. 7A and 7B together, although the filler may flow toward the second direction DR2 in the second region AR2, the flow may be partially blocked by the first protrusions EP1-1 and EP2-1 and the second protrusions EP1-2 and EP2-2. Accordingly, it is possible to suppress the second filling portion FM-G from overflowing in the second direction DR2 and sufficiently ensure the sealing region of the sealing member SML, thereby enhancing the bonding reliability of the display panel DP (see FIG. 6).

FIG. 7C illustrates a cross-section taken along a line II-II', which passes through the (2-1)-th protrusions EP1-21 of the first metal pattern ML1-P1 and a gap between the first metal pattern ML1-P1 and the second metal pattern ML1-P2.

Referring to FIG. 7C, the first substrate SUB1 may be a glass substrate, a metal substrate, or a polymer substrate. However, an embodiment of the inventive concept is not limited thereto, and the first substrate SUB1 may include an inorganic layer, an organic layer, or a composite material layer. Additionally, the first substrate SUB1 may have a multi-layer structure. For example, the first substrate SUB1 may include a synthetic resin layer, a multi-layered or single-layered inorganic layer, or a second synthetic resin layer disposed on the multi-layered or single-layered inorganic layer. Each of the first and second synthetic resin layers may include a polyimide (PI)-based resin, and an embodiment of the inventive concept is not particularly limited.

The circuit layer DP-CL of FIG. 7C may include at least one insulating layer and a circuit element. The circuit element includes signal lines, a pixel driving circuit, and the like. The circuit layer DP-CL may be formed through a process of forming the insulating layer, the semiconductor layer, and the conductive layer by coating, depositing, and a process of patterning the insulating layer, the semiconductor layer, and the conductive layer by a photolithographic process.

In an embodiment, a lower metal layer BML may be disposed on an upper surface of the first substrate SUB1. The lower metal layer BML may include molybdenum (Mo), a Mo-containing alloy, silver (Ag), an Ag-containing alloy, aluminum (Al), an Al-containing alloy, aluminum nitride (AIN), tungsten (W), tungsten nitride (WN), copper (Cu), titanium (Ti), p+ doped amorphous silicon, molybdenum-tantalum oxide (MoTaOx), and the like, but an embodiment of the inventive concept is not particularly limited thereto. The lower metal layer BML may include a light-blocking material and be referred to as a light-blocking layer.

The buffer layer BFL may be disposed on the first substrate SUB1 and cover the lower metal layer BML. The buffer layer BFL may include at least one inorganic layer. Semiconductor patterns SM of a transistor TR are disposed on the buffer layer BFL. The buffer layer BFL may enhance the bonding strength between the first substrate SUB1 and the semiconductor patterns SM and cover the lower metal layer BML.

The semiconductor patterns SM may include polysilicon. However, an embodiment of the inventive concept is not limited thereto, and the semiconductor patterns SM may also include amorphous silicon or a metal oxide. In FIG. 7C, only a portion of the semiconductor patterns SM is illustrated, and on a plane, the semiconductor patterns SM may be further disposed in other regions of pixels. The semiconductor patterns SM may be arranged across pixels of the display panel DP.

The semiconductor pattern SM may have different electrical properties depending on whether doping is applied or not. The semiconductor pattern SM may include a first region A1 having a low doping concentration and low conductivity and second regions S1 and D1 having relatively high doping concentrations and relatively high conductivities. One second region S1 may be disposed at one side of the first region A1, and the other second region D1 may be disposed at another side of the first region A1. The second regions S1 and D1 may be doped with an N-type dopant or a P-type dopant. For example, a P-type transistor is doped with the P-type dopant. The first region A1 may be an undoped region or doped with a lower concentration than the second regions S1 and D1.

The second regions S1 and D1 may substantially serve as an electrode or a signal line. The one second region S1 may correspond to a source electrode of the transistor TR, and the other second region D1 may correspond to a drain electrode of the transistor TR.

The first insulating layer INS1 may be disposed on the buffer layer BFL. The first insulating layer INS1 may overlap in common a plurality of the pixels disposed in the display region DA and cover the semiconductor pattern SM. The first insulating layer INS1 may be an inorganic layer and/or an organic layer, and may have a single-layer or multi-layer structure. The first insulating layer INS1 may include at least one among aluminum oxide, titanium oxide, silicon oxide, silicon oxynitride, zirconium oxide, and hafnium oxide. Like the first insulating layer INS1, the insulating layers of the circuit layer DP-CL to be described later may be an inorganic layer and/or an organic layer and have a single-layer or multi-layer structure.

A gate electrode G1 may be disposed on the first insulating layer INS1 and may be referred to as a gate G1. The gate G1 may be a portion of the metal pattern and overlap the first region A1. During a process of doping the semiconductor pattern, the gate G1 may function as a mask.

A second insulating layer INS2 may be disposed on the first insulating layer INS1 and cover the gate G1. The second insulating layer INS2 may overlap in common the plurality of the pixels.

An upper electrode UE may be disposed on the second insulating layer INS2. The upper electrode UE may overlap the gate G1. The upper electrode UE may include a single metal layer or multi-layered metal layers. The upper electrode UE may be omitted.

The third insulating layer INS3 may be disposed on the second insulating layer INS2 and cover the upper electrode UE. A source electrode SE and a drain electrode DE may be disposed on the third insulating layer INS3. Additionally, a connection signal line SCL may be disposed on the third insulating layer INS3. For example, the connection signal line SCL may correspond to a first power line PL1 (see FIG. 6). The first power line PL1 (see FIG. 6) and the source electrode SE and the drain electrode DE may be formed through the same process and include the same material.

The fourth insulating layer INS4 may be disposed on the third insulating layer INS3 and cover the source electrode SE, the drain electrode DE, and the connection signal line SCL. The fourth insulating layer INS4 may be an organic layer.

A connection electrode CNE may be disposed on the fourth insulating layer INS4. The connection electrode CNE may be connected to the drain electrode DE through a contact hole penetrating the fourth insulating layer INS4. The connection electrode CNE may include a low-resistance metal material. However, the configuration of the connection electrode CNE is not limited thereto and may be connected to the source electrode SE depending on the location thereof.

A fifth insulating layer INS5 may be disposed on the fourth insulating layer INS4. The fifth insulating layer INS5 may have a flat top surface such that a first electrode AE to be described later may be evenly formed. The fifth insulating layer INS5 may be an organic layer. After the fifth insulating layer INS5 is formed, a mechanical polishing may be performed to achieve the flat top surface.

A light-emitting element OLED may be disposed on the fifth insulating layer INS5. The light-emitting element OLED may include the first electrode AE, a light-emitting layer EML, and a second electrode CE. The first electrode AE may be connected to the connection electrode CNE through a contact hole penetrating the fifth insulating layer INS5. The first electrode AE may be an anode. The first electrode AE may be a transmissive electrode or transflective electrode. For example, the first electrode AE may include at least one among indium tin oxide (ITO), indium zinc oxide (IZO), zinc oxide (ZO), indium tin zinc oxide (ITZO), and a mixture thereof.

A pixel-defining film PDL may be disposed on the fifth insulating layer INS5. The pixel-defining film PDL has a pixel opening PDL-OP defined therein and extending to at least a portion of the first electrode AE. The pixel-defining film PDL may be an organic layer.

Although not illustrated, a hole control layer may further be disposed between the first electrode AE and the light-emitting layer EML. The hole control layer may include a hole transport layer and a hole injection layer.

The light-emitting layers EML may be disposed in regions corresponding to the pixel openings PDL-OP. The light-emitting layers EML may be formed to be separated from each other in the pixels. The light-emitting layer EML may include an organic material and/or an inorganic material. The light-emitting layer EML may emit red light, green light or the blue light. However, an embodiment of the inventive concept is not limited thereto, and the light-emitting layer EML may emit white light by combining organic materials that emit lights of red, green and blue.

Although not illustrated, an electronic control layer may further be disposed between the light-emitting layer EML and the second electrode CE. The electronic control layer may be disposed on the hole control layer to cover the light-emitting layer EML. The electronic control layer may include an electron transport layer and an electron injection layer.

The second electrode CE may be disposed on the light-emitting layer EML. The second electrode CE may be disposed in common in the pixels. The second electrode CE may be connected to the power line PL through a connection electrode CCL. The second electrode CE may receive the second voltage ELVSS, which is a common power voltage, through the power line PL.

The connection electrode CCL and the first electrode AE may be formed through the same process and include the same material. Through a contact hole that is formed in the non-display region NDA, a lower surface of the connection electrode CCL may be in contact with an upper surface of the power line PL. Additionally, since an upper surface of the connection electrode CCL and the second electrode CE may be electrically connected, the second electrode CE may be supplied with the second voltage ELVSS from the power line PL.

Although not illustrated, the encapsulation layer may be disposed on the display element layer DP-OLED to protect the light-emitting element OLED. The filler FML may be disposed on the display element layer DP-OLED and fill an empty space between the first substrate SUB1 and the second substrate SUB2, thereby protecting the display panel DP from an external impact.

In an embodiment, the sealing member SML may include an upper surface SML-US in contact with the second substrate SUB2 and a lower surface SML-DS in contact with the fourth insulating layer INS4. Within a region in which the sealing member SML overlaps the second region AR2, a length of the upper surface SML-US of the sealing member in the second direction DR2 may be greater than a length of the lower surface SML-DS of the sealing member. That is, since the filler FML may displace the sealing member SML in the second direction DR2 and a step may be formed in the third direction DR3 within the second region AR2, the lengths of the upper surface SML-US and the lower surface SML-DS of the sealing member in the second direction DR2 may be different.

In an embodiment, the (2-1)-th protrusion EP1-21 may be disposed on the same layer as the lower metal layer BML. That is, the first metal layer ML1 (see FIG. 7A) and the lower metal layer BML may include the same material and be formed through the same process. However, an embodiment of the inventive concept is not limited thereto, and the first metal layer ML1 (see FIG. 7A) and the gate electrode G1 may include the same material and also be disposed on the same layer.

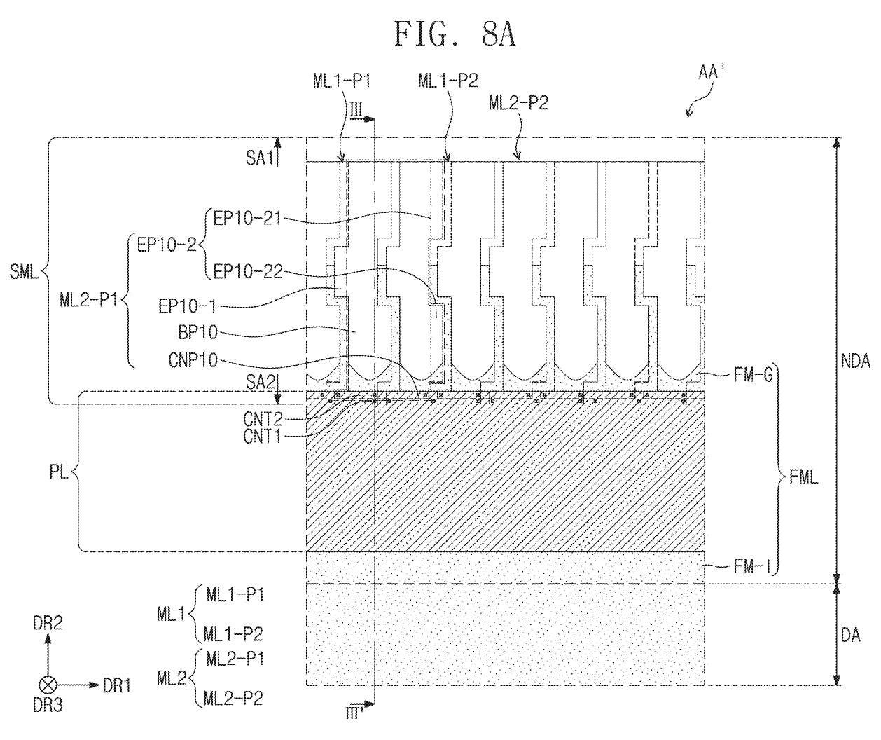

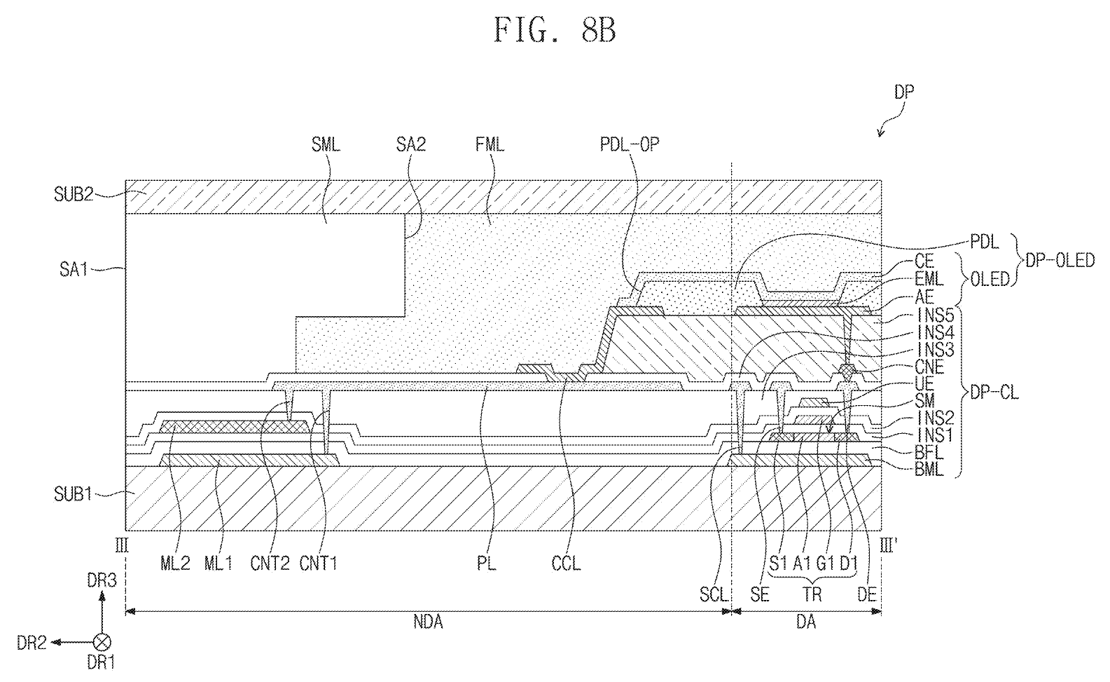

FIG. 8A is an enlarged plan view of a portion of the display panel DP according to an embodiment of the inventive concept. FIG. 8B is a cross-sectional view of the display panel DP according to an embodiment of the inventive concept. For the reference numerals or symbols that are duplicated with those described with reference to FIGS. 7A and 7C, the descriptions thereof are omitted, and it will be understood that the elements represented by the same or similar reference numerals or symbols may have the substantially the same or similar structure or configuration as each other.

Referring to FIG. 8A, the display panel DP may further include a second metal layer ML2 that is disposed on a layer different from a layer on which the first metal layer ML1 is disposed. The second metal layer ML2 may be disposed on the non-display region NDA and be electrically connected to the power line PL through a second contact hole CNT2. The first metal layer ML1 and the second metal layer ML2 are alternately arranged in the first direction DR1. In FIG. 8A, for convenience, the first metal layer ML1 is denoted by a solid line, and the second metal layer ML2 is denoted by a dotted line.

In an embodiment, the second metal layer ML2 may include a third metal pattern ML2-P1 and a fourth metal pattern ML2-P2, which are disposed spaced apart from each other on a plane. In the first direction DR1, the first metal pattern ML1-P1 and the second metal pattern ML1-P2 may be arranged in a staggered arrangement with the third metal pattern ML2-P1 and the fourth metal pattern ML2-P2, respectively.

The third metal pattern ML2-P1 and the fourth metal pattern ML2-P2 are illustrated as an example, and the number of the metal patterns is not limited. The third metal pattern ML2-P1 and the fourth metal pattern ML2-P2 may be spaced apart from each other in the first direction DR1 and spaced apart along the edge direction of the first substrate SUB1 (see FIG. 6). Each of the second metal layers ML2 may also be arranged in an island shape or an isolated shape. In FIG. 8A, slits are not illustrated but a plurality of slits SLT (see FIG. 7A) may further be included.

In an embodiment, the first contact hole CNT1 may be disposed closer to the display region DA than the second contact hole CNT2 in the second direction DR2. The second metal layer ML2 may be located farther away from the display region DA than the first metal layer ML1 in the second direction DR2.

On a plane, the third metal pattern ML2-P1 may include a base portion BP10 extending in the second direction DR2, a connection portion CNP10 including the second contact hole CNT2, at least one first protrusion EP10-1 protruding from the base portion BP10 toward one side in the first direction DR1, and at least one second protrusion EP10-2 protruding from the base portion BP10 toward the other side in the first direction DR1. The first protrusion EP10-1 of the third metal pattern ML2-P1 and the first protrusion EP1-1 (see FIG. 7A) of the first metal pattern ML1-P1 may protrude in the same direction, and the second protrusion EP10-2 of the third metal pattern ML2-P1 and the second protrusion EP1-2 of the first metal pattern ML1-P1 may protrude in the same direction.

In an embodiment, the base portion BP10 of the third metal pattern ML2-P1 may be disposed to overlap a space between the first metal pattern ML1-P1 and the second metal pattern ML1-P2 in a third direction DR3. In other words, the third metal pattern ML2-P1 may be arranged in a staggered arrangement with the first metal pattern ML1-P1 and the second metal pattern ML1-P2 in the first direction DR1 on a plane.

The first protrusion EP10-1 of the third metal pattern ML2-P1 may overlap the base portion BP1 (see FIG. 7A) of the first metal pattern ML1-P1, and the second protrusion EP10-2 of the third metal pattern ML2-P1 may overlap the base portion BP2 (see FIG. 7A) of the second metal pattern ML1-P2. Accordingly, the first metal layer ML1 and the second metal layer ML2 may be arranged in a staggered arrangement with each other in the first direction DR1.

FIG. 8B is a cross-sectional view of the display panel DP taken along a line III-III' of FIG. 8A.

FIG. 8B illustrates a stacked relation between the first metal layer ML1 and the second metal layer ML2. As illustrated in FIG. 8B, the first metal layer ML1 and the lower metal layer BML may be disposed on the same layer. The first metal layer ML1 and the lower metal layer BML may include the same material and be formed through the same process. The first metal layer ML1 may be disposed on the same layer as the lower metal layer BML, and may be connected to the power line PL through the first contact hole CNT1. The second metal layer ML2 may be disposed on the same layer as the gate electrode G1, and may be connected to the power line PL through the second contact hole CNT2. The second metal layer ML2 and the gate electrode G1 may include the same material and be formed through the same process.

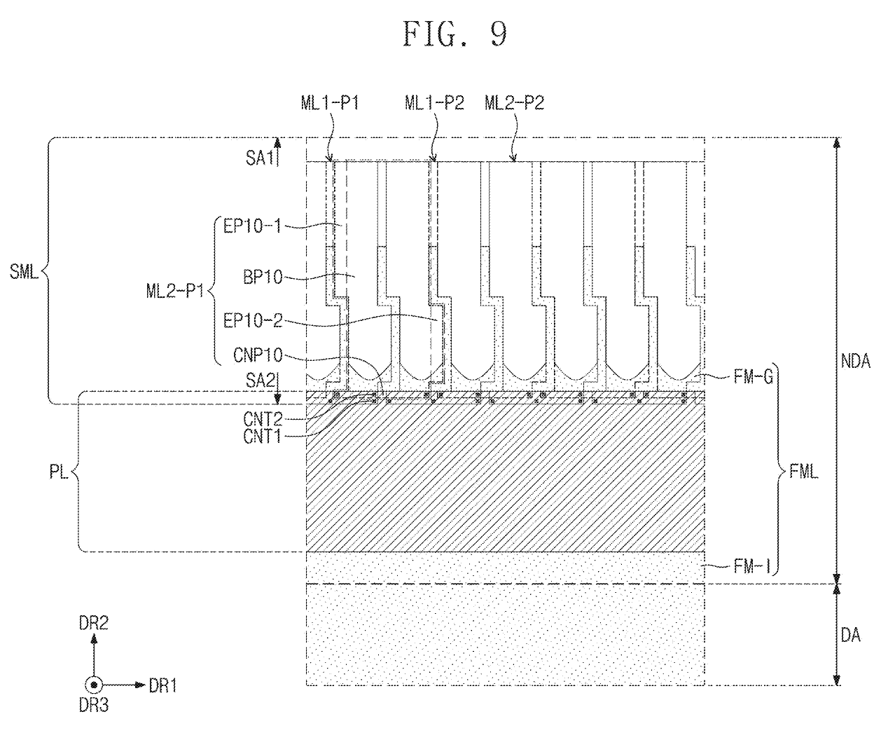

FIG. 9 is an enlarged plan view of a portion of a display panel according to an embodiment of the inventive concept. FIG. 9 is an enlarged plan view schematically illustrating a region of AA' of FIG. 6 according to an embodiment. For the reference numerals or symbols that are duplicated with those described with reference to FIGS. 7A and 8A, the descriptions are omitted, and it will be understood that the elements represented by the same or similar reference numerals or symbols may have the substantially the same or similar structure or configuration as each other.

Referring to FIG. 9, the third metal pattern ML2-P1 includes a single first protrusion EP10-1 and a single second protrusion EP10-2. A length of the first protrusion EP10-1 in the second direction DR2 may be greater than a length of the second protrusion EP10-2 in the second direction DR2. As the number of protrusions of the metal patterns decreases, the number of bending of the metal patterns may decrease. Accordingly, the filler may further flow toward the second direction DR2, and thus a length of the second filling portion FM-G in the second direction DR2 may be extended compared to that of FIG. 8A. However, as the bending portion is still formed at the entrance through which the second filling portion FM-G flows, the flow of the filler FML may be suppressed.

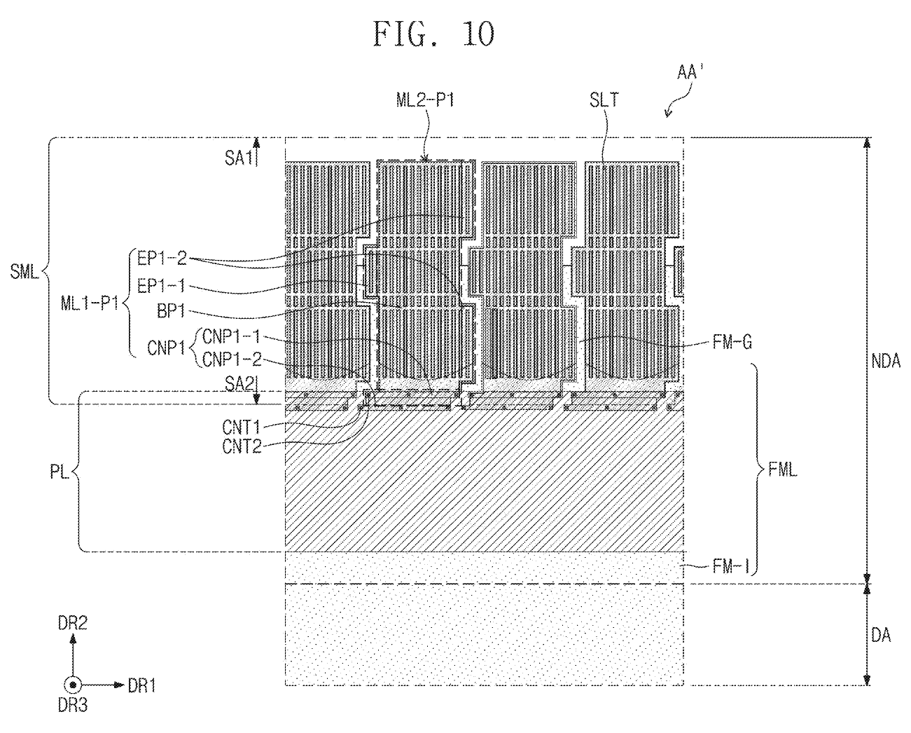

FIG. 10 is an enlarged plan view of a portion of a display panel according to an embodiment of the inventive concept. FIG. 10 is an enlarged plan view schematically illustrating a region of AA' in FIG. 6 according to an embodiment. For the reference numerals or symbols that are duplicated with those described with reference to FIG. 7A, the descriptions are omitted, and it will be understood that the elements represented by the same or similar reference numerals or symbols may have the substantially the same or similar structure or configuration as each other.

Referring to FIG. 10, the first metal pattern ML1-P1 and the third metal pattern ML2-P1 may overlap in the third direction DR3. As illustrated in FIG. 10, a length of the first metal pattern ML1-P1 in the second direction DR2 may be greater than a length of the third metal pattern ML2-P1 in the second direction DR2.

In an embodiment, the connection portion CNP1 of the first metal pattern ML1-P1 of the first metal layer may include a first connection portion CNP1-1 which extends from the base portion BP1 in the second direction DR2 and partially protrudes from the base portion BP1 toward one side in the first direction DR1, and a second connection portion CNP1-2 which extends from the first connection portion CNP1-1 in the second direction DR2 and partially protrudes from the first connection portion CNP1-1 toward one side in the first direction DR1. The first metal pattern ML1-P1 may be connected to the power line PL through the first contact hole CNT1 included in the second connection portion CNP1-2 of the first metal pattern ML1-P1.

Since each of the first connection portion CNP1-1 and the second connection portion CNP1-2 protrudes in the first direction DR1, additional bending portion may be formed at the entrance through which the second filling portion FM-G flows. Accordingly, although the first metal pattern ML1-P1 and the third metal pattern ML2-P1 overlap in the third direction DR3, overflow of the filleter FML toward the sealing member SML may be suppressed.

A display device according to an embodiment of the inventive concept and an electronic device including the same may include a plurality of metal patterns that are electrically connected to a power line and spaced apart from each other, thereby suppressing static electricity from being introduced into a display region. The metal pattern may include a base portion and a protrusion protruding from the base portion to block the flow of a filler, thereby controlling a path through which the filler flows into the space between adjacent metal patterns during a process of bonding the display device. Accordingly, it is possible to prevent a sealing member from being displaced by the filler during the bonding process and to ensure a sealing area, thereby improving the quality and reliability of the display device.

Although the above has been described with reference to embodiments of the inventive concept, those skilled in the art or those of ordinary skill in the art may understand that various modifications and changes may be made to the inventive concept insofar as such modifications and changes do not depart from the spirit and technical feature of the inventive concept set forth in the claims to be described later. Therefore, the technical scope of the inventive concept is not to be limited to the contents stated in the detailed description of the specification, but should be determined by the claims.

What is claimed is:

1. A display device comprising:
a first substrate including a display region and a non-display region surrounding at least a portion of the display region;
a pixel arranged in the display region of the first substrate;
a second substrate facing the first substrate;
a filler disposed between the first substrate and the second substrate;
a sealing member disposed between the first substrate and the second substrate and overlapping the non-display region;
a first metal layer disposed in the non-display region; and
a power line disposed in the non-display region and electrically connected to the pixel,
wherein the first metal layer includes a first metal pattern and a second metal pattern, each of the first metal pattern and the second metal pattern being electrically connected to the power line through a first contact hole, and the second metal pattern being spaced apart from the first metal pattern in a first direction, and
wherein the first metal pattern includes:
a base portion extending in a second direction crossing the first direction;
a connection portion disposed closer to the display region than the base portion in the second direction and including the first contact hole;
a first protrusion protruding from the base portion toward a first side in the first direction; and
a second protrusion protruding from the base portion toward a second side in the first direction.

2. The display device of claim 1, wherein the sealing member overlaps the base portion, and the filler overlaps the connection portion.

3. The display device of claim 1, wherein the second metal pattern comprises:
a base portion extending in the second direction;
a connection portion disposed closer to the display region than the base portion in the second direction and including the first contact hole;
a first protrusion protruding from the base portion toward the first side in the first direction; and
a second protrusion protruding from the base portion toward the second side in the first direction,
the second protrusion of the first metal pattern includes a (2-1)-th protrusion and a (2-2)-th protrusion, which are spaced apart from each other in the second direction, and
the first protrusion of the second metal pattern is disposed between the (2-1)-th protrusion and the (2-2)-th protrusion of the first metal pattern in the second direction.

4. The display device of claim 1, further comprising at least one insulating layer disposed on the first substrate and covering the first metal pattern and the second metal pattern,
wherein a step is defined in the at least one insulating layer between a first region, overlapping the first metal pattern and the second metal pattern, and a second region, disposed between the first metal pattern and the second metal pattern.

5. The display device of claim 4, wherein the sealing member comprises an upper surface in contact with the second substrate and a lower surface in contact with the at least one insulating layer, and
within the second region, a length of the upper surface in the second direction is greater than a length of the lower surface in the second direction.

6. The display device of claim 1, wherein a length of the connection portion in the first direction is greater than a length of the base portion in the first direction.

7. The display device of claim 1, wherein each of the first metal pattern and the second metal pattern comprises a plurality of slits extending in the second direction.

8. The display device of claim 1, further comprising a lower metal layer,
wherein the pixel includes a transistor including a semiconductor pattern and a gate electrode overlapping the semiconductor pattern,
the lower metal layer is disposed between the first substrate and the semiconductor pattern, and
the first metal layer and the lower metal layer comprise a same material and are disposed on a same layer.

9. The display device of claim 1, wherein the pixel comprises a transistor including a semiconductor pattern and a gate electrode overlapping the semiconductor pattern, and
the first metal layer and the gate electrode comprises a same material and are disposed on a same layer.

10. The display device of claim 1, further comprising a second metal layer located in the non-display region and disposed on a different layer different from the first metal layer,
wherein the second metal layer includes a third metal pattern and a fourth metal pattern spaced apart from the third metal pattern in the first direction, each of the third metal pattern and the fourth metal pattern being electrically connected to the power line through a second contact hole, and
the first contact hole is disposed closer to the display region than the second contact hole in the second direction.

11. The display device of claim 10, wherein the third metal pattern comprises:
a base portion extending in the second direction;
a connection portion including the second contact hole;
a first protrusion protruding from the base portion toward the first side in the first direction; and
a second protrusion protruding from the base portion toward the second side in the first direction, and
wherein the base portion of the third metal pattern overlaps a space between the first metal pattern and the second metal pattern.

12. The display device of claim 11, wherein the first protrusion of the third metal pattern overlaps a portion of the base portion of the first metal pattern, and
the second protrusion of the third metal pattern overlaps a portion of the base portion of the second metal pattern.

13. The display device of claim 10, further comprising a lower metal layer,
wherein the pixel includes a transistor including a semiconductor pattern and a gate electrode overlapping the semiconductor pattern,
the lower metal layer is disposed between the first substrate and the semiconductor pattern,
the first metal layer and the lower metal layer include a same material and are disposed on a same layer, and
the second metal layer and the gate electrode include a same material and are disposed on a same layer.

14. The display device of claim 1, wherein a length of the first protrusion in the second direction is greater than a length of the second protrusion in the second direction.

15. The display device of claim 1, wherein the connection portion comprises:
a first connection portion extending from the base portion in the second direction and partially protruding from the base portion toward the first side in the first direction; and
a second connection portion extending from the first connection portion in the second direction and partially protruding from the first connection portion toward the first side in the first direction.

16. The display device of claim 1, further comprising a second metal layer disposed in the non-display region and disposed on a different layer from the first metal layer,
wherein the first metal layer and the second metal layer are arranged in a staggered arrangement along the first direction on a plane.

17. The display device of claim 1, further comprising a second metal layer disposed in the non-display region and disposed on a different layer from the first metal layer,
wherein the second metal layer includes a third metal pattern and a fourth metal pattern spaced apart from the third metal pattern in the first direction, each of the third metal pattern and the fourth metal pattern being electrically connected to the power line through a second contact hole, and
the first metal pattern and the second metal pattern are arranged in a staggered arrangement with the third metal pattern and the fourth metal pattern along the first direction on a plane.

18. An electronic device comprising:
a display module;
a window disposed on the display module; and
a power module disposed under the display module,
wherein the display module includes:
a first substrate including a display region and a non-display region surrounding at least a portion of the display region;
a pixel arranged in the display region of the first substrate;
a second substrate facing the first substrate;
a filler disposed between the first substrate and the second substrate;
a sealing member disposed between the first substrate and the second substrate and overlapping the non-display region;
a first metal layer disposed in the non-display region; and
a power line disposed in the non-display region and electrically connected to the pixel, and
wherein the first metal layer includes a first metal pattern and a second metal pattern, each of the first metal pattern and the second metal pattern being electrically connected to the power line through a first contact hole, and the second metal pattern being spaced apart from the first metal pattern in a first direction, and
wherein the first metal pattern includes:
a base portion extending in a second direction crossing the first direction;
a connection portion disposed closer to the display region than the base portion in the second direction and including the first contact hole;
a first protrusion protruding from the base portion toward a first side in the first direction; and
a second protrusion protruding from the base portion toward a second side in the first direction.

19. The electronic device of claim 18, wherein the sealing member overlaps the base portion, and the filler overlaps the connection portion.

20. The electronic device of claim 18, wherein the second metal pattern comprises:
a base portion extending in the second direction;
a connection portion disposed closer to the display region than the base portion in the second direction and including the first contact hole;
a first protrusion protruding from the base portion toward the first side in the first direction; and
a second protrusion protruding from the base portion toward the second side in the first direction,
the second protrusion of the first metal pattern includes a (2-1)-th protrusion and a (2-2)-th protrusion, which are spaced apart from each other in the second direction, and
the first protrusion of the second metal pattern is disposed between the (2-1)-th protrusion and the (2-2)-th protrusion of the first metal pattern in the second direction.
